(19) United States
(12) Patent Application Publication
(10) Pub. No.: US 2010/0025742 A1
(43) Pub. Date: Feb. 4, 2010

(54) TRANSISTOR HAVING A STRAINED CHANNEL REGION CAUSED BY HYDROGEN-INDUCED LATTICE DEFORMATION

(76) Inventors: Sven Beyer, Dresden (DE); Andreas Hellmich, Dresden (DE); Gunter Grasshoff, Radebeul (DE); Hans-Juergen Engelmann, Dresden (DE)

Correspondence Address: WILLIAMS, MORGAN & AMERSON, 10333 RICHMOND, SUITE 1100, HOUSTON, TX, 77042, US

(21) Appl. No.: 12/476,376

(22) Filed: Jun. 2, 2009

(30) Foreign Application Priority Data
Jul. 31, 2008 (DE) 10 2008 035 811.8

(51) Int. Cl. H01L 29/78; H01L 21/336

(52) U.S. Cl. 257/288; 438/305; 257/E21.409; 257/E29.255

(57) ABSTRACT

A lattice distortion may be achieved by incorporating a hydrogen species into a semiconductor material, such as silicon, without destroying the lattice structure. For example, by incorporating the hydrogen species on the basis of an electron shower, a tensile strain component may be obtained in the channel of N-channel transistors.

### BACKGROUND OF THE INVENTION

1. Field of the Invention

Generally, the present disclosure relates to the field of integrated circuits, and, more particularly, to transistors having strained channel regions to enhance charge carrier mobility in the channel region of a MOS transistor.

2. Description of the Related Art

Integrated circuits typically include a very large number of circuit elements, such as transistors, capacitors and the like, wherein field effect transistors are frequently used as transistor elements, in particular when complex digital circuit portions are considered. Generally, a plurality of process technologies are currently practiced, wherein, for complex circuitry, such as microprocessors, storage chips and the like, CMOS technology is currently one of the most promising approaches for forming field effect transistors due to the superior characteristics in view of operating speed and/or power consumption and/or cost efficiency. During the fabrication of complex integrated circuits using CMOS technology, millions of transistors, i.e., N-channel transistors and P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely doped channel region disposed between the drain region and the source region. The conductivity of the channel region, i.e., the drive current capability of the conductive channel, is controlled by a gate electrode formed close to the channel region and separated therefrom by a thin insulating layer. The conductivity of the channel region, upon formation of a conductive channel due to the application of an appropriate control voltage to the gate electrode, depends on the dopant concentration, the mobility of the majority charge carriers and, for a given extension of the channel region in the transistor width direction, on the distance between the source and drain regions, which is also referred to as channel length. Hence, the conductivity of the channel region is a dominant factor determining the performance of MOS transistors.

The continuing shrinkage of the transistor dimensions for reducing the channel length and thus the channel resistance per unit length, however, involves a plurality of issues associated therewith, such as reduced controllability of the channel, also referred to as short channel effects, and the like, that have to be addressed so as to not unduly offset the advantages obtained by steadily decreasing the channel length of MOS transistors. The continuous size reduction of the critical dimensions, i.e., the gate length of the transistors, necessitates the adaptation and possibly the new development of highly complex process techniques, for example, for compensating for short channel effects. It has, therefore, been proposed to also enhance the channel conductivity of the transistor elements by increasing the charge carrier mobility in the channel region for a given channel length, thereby offering the potential for achieving a performance improvement that is comparable with the advance to a future technology node while avoiding or at least postponing many of the problems encountered with the process adaptations associated with device scaling.

One efficient mechanism for increasing the charge carrier mobility is the modification of the lattice structure in the channel region, for instance by creating tensile or compressive stress in the vicinity of the channel region to produce a corresponding strain in the channel region, which results in a modified mobility for electrons and holes, respectively. For example, creating uniaxial tensile strain in the channel region along the channel length direction for a standard crystallographic orientation increases the mobility of electrons, which in turn may directly translate into a corresponding increase in the conductivity. On the other hand, uniaxial compressive strain in the channel region for the same crystalline configuration may increase the mobility of holes, thereby providing the potential for enhancing the performance of P-type transistors. The introduction of stress or strain engineering into integrated circuit fabrication is therefore an extremely promising approach for further device generations, since strained silicon may be considered as a “new” type of semiconductor material, which may enable the fabrication of fast powerful semiconductor devices without requiring expensive semiconductor materials, while many of the well-established manufacturing techniques may still be used.

In some approaches, external stress created by, for instance, permanent overlaying layers, spacer elements and the like is used in an attempt to create a desired strain within the channel region. Although a promising approach, the process of creating the strain in the channel region by applying a specified external stress may depend on the efficiency of the stress transfer mechanism for the external stress provided, for instance, by contact layers, spacers and the like into the channel region to create the desired strain therein. Thus, for different transistor types, differently stressed overlayers have to be provided, which may result in a plurality of additional process steps, wherein, in particular, any additional lithography steps may significantly contribute to the overall production costs.

In still a further approach, a substantially amorphized region may be formed adjacent to the gate electrode at an intermediate manufacturing stage, which may then be re-crystallized in the presence of a “rigid” overlying layer formed above the transistor area. During the anneal process for re-crystallizing the lattice, the growth of the crystal will occur under specific stress conditions created by the overlayer and result in a tensile strained crystal, which may be advantageous for N-channel transistors, as explained above. After the re-crystallization, the sacrificial stress layer may be removed, wherein, nevertheless, a certain amount of strain may be “conserved” in the re-grown lattice portion. This effect is generally known as stress memorization. Although the exact mechanism is not yet fully understood, it is believed that, during the anneal process, the interaction of the rigid overlayer with the highly damaged or amorphous silicon material may suppress a volume reduction of the re-crystallizing silicon lattice, which may therefore remain in a tensile-strained state.

The approach of a stress memorization technique may be a promising concept for introducing strain internally in the active region of N-channel transistors without requiring additional materials, such as semiconductor alloys and the like, which may require sophisticated selective epitaxial growth techniques and the like. The conventional stress memorization techniques may require a significant crystalline damage in order to obtain a desired high degree of strain upon re-crystallization of the damaged lattice portion in the presence of the rigid overlayer. Therefore, corresponding stress memorization techniques may have to be thoroughly implemented into the overall manufacturing flow in order to obtain a desired high gain in performance of N-channel transistors without unduly contributing to the overall complexity of the manufacturing sequence.

In addition to stress memorization techniques, other strain-inducing mechanisms may be implemented in order to obtain a combined effect of the various mechanisms, while at the same time maintaining the degree of complexity of the overall process flow at an acceptable level. Consequently, there is a continuous search for additional performance increasing-mechanisms, in particular with respect to strain mechanisms, in order to further enhance overall device performance without unduly affecting process complexity.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides techniques and semiconductor devices in which a semiconductor material, such as a silicon-based semiconductor material, may be distorted substantially without destroying the lattice structure on the basis of hydrogen, which may be driven into the crystalline semiconductor material without causing undue lattice damage. The distorted lattice structure may be advantageously used in cases in which electronic characteristics of the semiconductor material may have to be modified, for instance, with respect to charge carrier mobility and the like. Hence, in some illustrative aspects disclosed herein, the lattice distortion may be initiated in the vicinity of a silicon-containing channel region of a field effect transistor, thereby also inducing a corresponding strain in the channel region, which may thus translate into enhanced transistor performance, as previously discussed. For example, the hydrogen species incorporated into the silicon-based semiconductor material may result in a “swelling” of the corresponding portions, which may thus lead to a corresponding contraction in the direction perpendicular to the “swelling” direction, thereby creating a tensile strain in the adjacent channel region. Hence, the mechanism may be advantageously used in N-channel field effect transistors, in which the hydrogen species may be efficiently driven into the active region adjacent to a gate electrode structure, thereby obtaining the desired tensile strain component in the channel region. The distortion of the semiconductor material in a substantially crystalline state may also be applied to any other semiconductor devices in which lattice distortion without significant lattice damage may be advantageously employed for enhancing overall device characteristics. In some illustrative aspects, the driving in of the hydrogen species into the semiconductor material may be accomplished on the basis of an electron “shower,” i.e., an electron bombardment in the presence of a hydrogen-containing material layer, which may be provided in the form of a hydrogen-rich material layer, i.e., a material layer having a typical stoichiometric formula, in which the actual amount of hydrogen may be higher compared to the fraction as indicated by the stoichiometric formula.

One illustrative method disclosed herein comprises forming a gate electrode structure above an active region located in a silicon-containing crystalline semiconductor layer. The method further comprises driving a hydrogen species into an exposed surface portion of the crystalline semiconductor layer so as to deform a lattice structure of at least a portion of the active region.

A further illustrative method disclosed herein comprises forming a hydrogen-containing material layer on a crystalline semiconductor layer and performing an electron bombardment on the hydrogen-containing material layer so as to create a strained crystalline state of at least a portion of the crystalline semiconductor layer.

One illustrative field effect transistor disclosed herein comprises an active region comprising silicon material in a crystalline state. The field effect transistor further comprises drain and source regions formed in the active region, wherein the drain and source regions comprise a strain-inducing region having a distorted lattice structure. The strain-inducing region has a higher hydrogen concentration compared to remaining areas of the active region. Furthermore, the field effect transistor comprises a gate electrode structure formed on a channel region of the active region.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a semiconductor device including a silicon-containing crystalline semiconductor layer in portions of which a hydrogen species is driven so as to obtain a distorted lattice structure, which may be advantageously used for forming sophisticated semiconductor devices, according to illustrative embodiments;

FIGS. 1b-1f schematically illustrate cross-sectional views of the semiconductor device of FIG. 1a when representing a field effect transistor, wherein a lattice distortion may be created after forming drain and source extension regions, according to further illustrative embodiments; and

FIGS. 1g-1h schematically illustrate cross-sectional views of the field effect transistor in a further advanced manufacturing stage in which, prior to a silicidation process, a further sequence of driving in a hydrogen species into portions of the active region of the transistor may be performed, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to techniques and semiconductor devices in which the lattice structure of a semiconductor material, such as a silicon-containing semiconductor material, may be efficiently distorted substantially without causing significant lattice damage of the crystalline state by driving in a hydrogen species. It has been recognized that hydrogen may be incorporated into a semiconductor material, for instance a silicon-containing layer, without substantially destroying the lattice structure, while nevertheless providing a significant distortion thereof. For example, in the presence of a hydrogen species on exposed surface portions of the crystalline semiconductor material, an efficient incorporation may be achieved, thereby resulting in a “swelling” or deformation along the layer thickness direction, which may result in a tensile strain component in a lateral direction perpendicular to the depth direction. In some illustrative embodiments, the distorted lattice structure may be provided adjacent to a gate electrode structure, thereby causing a desired uniaxial tensile strain component in the adjacent channel region, which may thus enhance electron mobility in the current flow direction, which may result in enhanced drive current capability. It should be appreciated that, although the mechanism of incorporating a hydrogen species substantially without destroying the lattice structure may be advantageously applied to N-channel transistors in other cases, any other circuit elements, such as P-channel transistors and the like, may be modified on the basis of an efficient strain-inducing mechanism by taking into consideration specific aspects, such as the overall crystalline orientation of the semiconductor material and the like. For example, the current flow direction of channel regions of P-channel transistors may be appropriately selected so that a lateral tensile strain component created in the vicinity of the channel region may result in enhanced transistor performance. Thus, although various embodiments disclosed herein may refer to an N-channel transistor, which may have enhanced drive current capability due to a tensile strain component, the present disclosure should not be considered as being restricted to N-channel transistors unless such restrictions are explicitly set forth in the specification and/or the appended claims.

In some illustrative embodiments disclosed herein, an efficient incorporation of a hydrogen species may be accomplished on the basis of a hydrogen-containing material layer, which, in some embodiments, may be provided in the form of a hydrogen-rich material layer, which may be understood as a material layer in which the fraction of hydrogen may be higher compared to the fraction of hydrogen given by a corresponding stoichiometric formula for the material composition under consideration. For example, a silicon nitride material may typically be described as a dielectric material having a composition as given by the stoichiometric formula Si₃N₄, wherein actually a certain amount of hydrogen may be incorporated due to the deposition mechanism, such as plasma enhanced chemical vapor deposition (CVD), thermally activated CVD and the like. For instance, a hydrogen content of approximately one to several atomic percent compared to the silicon and nitrogen contents may be encountered and may be considered as a hydrogen-rich silicon nitride material. In other cases, hydrogen may be incorporated into other dielectric materials, such as silicon dioxide, silicon oxynitride and the like, in an amount which is actually not represented by the stoichiometric formula of these material compositions, thereby also providing a hydrogen-rich material. It has surprisingly been recognized that an efficient incorporation of hydrogen species into portions of the semiconductor material covered by the hydrogen-containing material layer may be initiated, according to some illustrative embodiments, by using an electron “shower.” A corresponding electron shower may be accomplished by generating an electron beam or any other electron bombardment by using any appropriate device enabling the acceleration of electrons onto a specific target. The electron bombardment may be accomplished as a scanning electron beam or by establishing an appropriate plasma ambient, in which the electron cloud may be in contact with the hydrogen-containing material layer. Without intending to restrict the present disclosure to any explanation, it is believed that, although the mechanism for driving hydrogen species from a hydrogen-containing layer into a crystalline semiconductor material is not understood, upon positioning charge carriers in the form of “hot electrons” within the material layer, the hydrogen species diffuses into the lower lying crystalline semiconductor material, wherein, however, the incorporation of the hydrogen species may result in a distortion substantially along the depth direction, while a lateral distortion may be substantially suppressed by the overlying material layer. After the removal of the material layer, or at least a significant portion thereof, a corresponding lateral strain component may be obtained. However, although the mechanism is not presently understood, a mechanism of incorporating a hydrogen species may be advantageously applied during semiconductor production techniques, since process parameters affecting the overall strain-inducing mechanism may be well controlled and may be correlated with a corresponding modification of the overall device characteristics on the basis of respective experimental data. Consequently, an efficient additional strain-inducing mechanism may be obtained on the basis of the incorporation of a hydrogen species, as explained above.

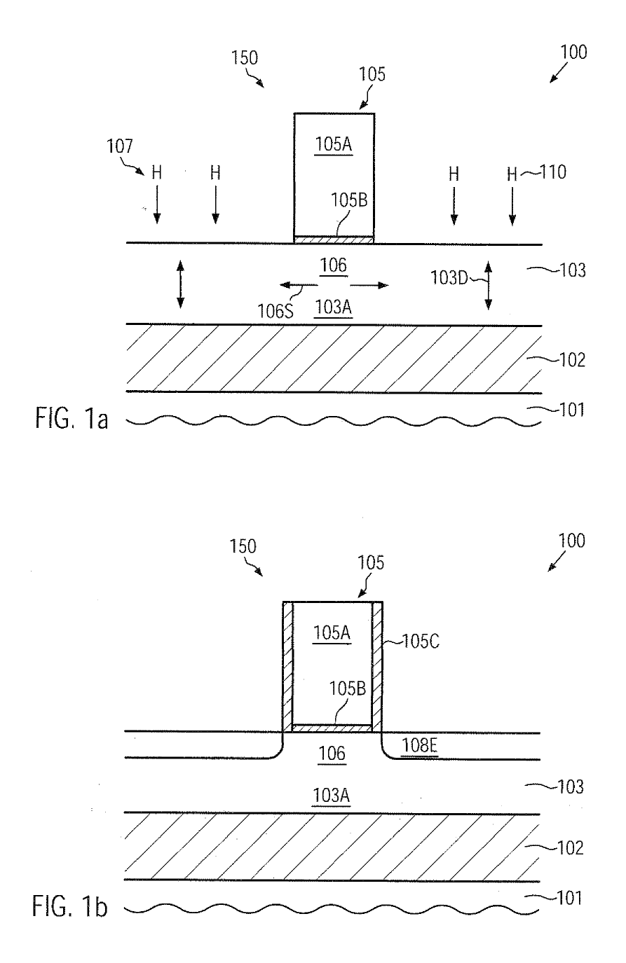

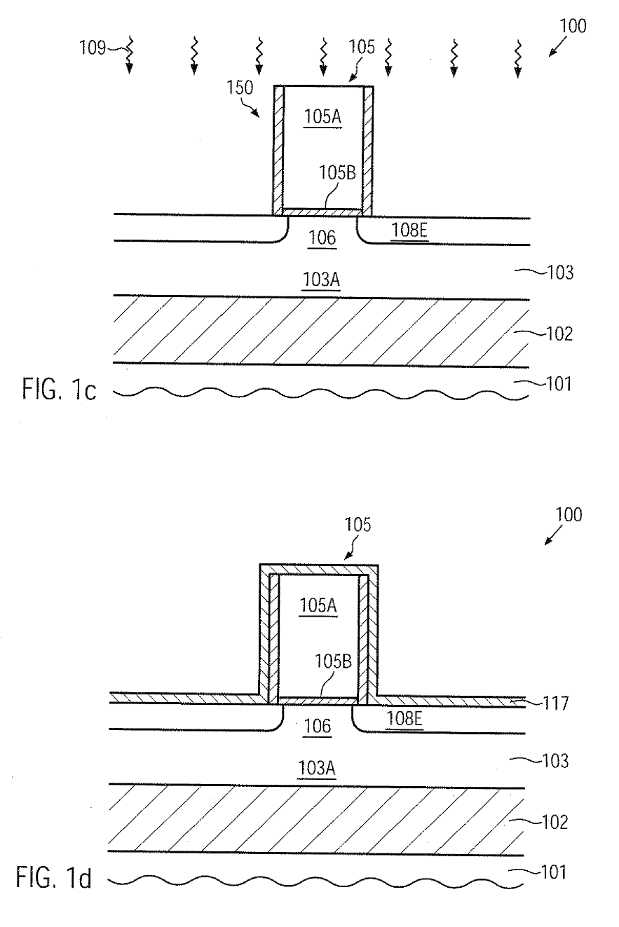

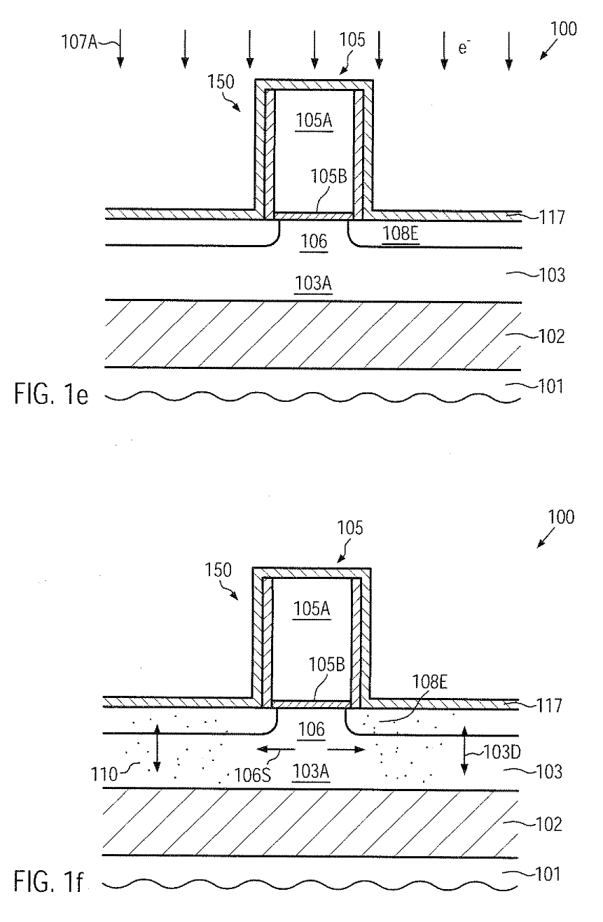

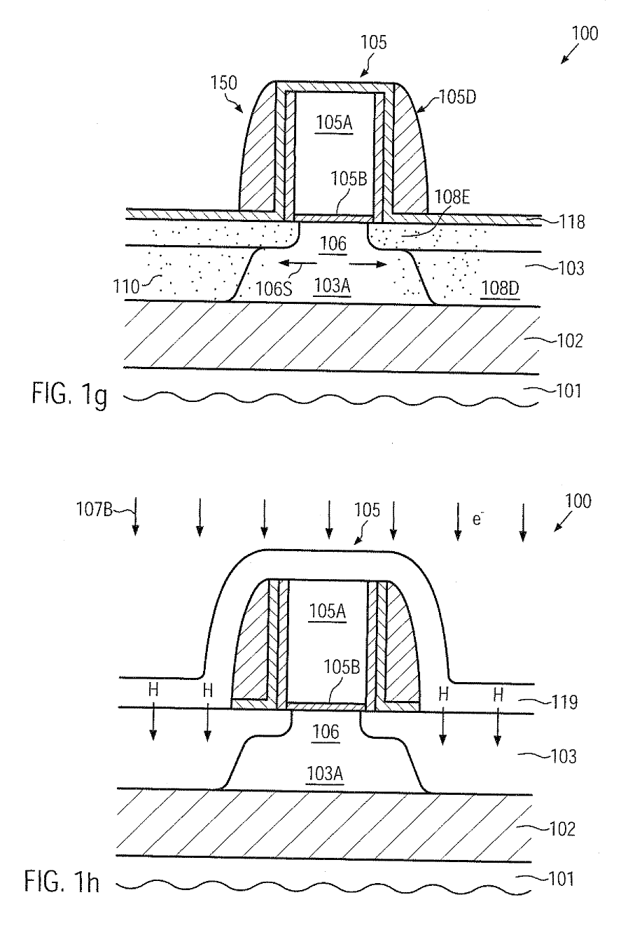

FIG. 1a schematically illustrates a cross-sectional view of a semiconductor device 100 comprising a substrate 101, above which may be formed a semiconductor layer 103. The substrate 101 may represent any appropriate carrier material, such as a semiconductor material, an insulating material and the like, depending on the overall device requirements. The semiconductor layer 103 may represent a semiconductor material in a substantially crystalline state wherein, in some illustrative embodiments, the semiconductor layer 103 may comprise a silicon material, the electronic characteristics of which may be modified by creating a certain type of strain, at least in portions of the semiconductor layer 103. In the embodiment shown, a buried insulating layer 102, for instance in the form of a silicon dioxide material, silicon nitride and the like, may be provided between the substrate 101 and the semiconductor layer 103, thereby defining a silicon-on-insulator (SOI) architecture. In other cases, the buried insulating layer 102 may not be provided or may be omitted at least in certain device areas of the semiconductor device 100. The semiconductor layer 103 may be used as a base material for forming therein and thereon corresponding circuit elements, such as transistors, capacitors and the like, wherein the overall conductivity of portions of the semiconductor layer 103 may be adjusted in any appropriate manner, for instance by forming corresponding PN junctions therein, as may be required for the operational behavior of the corresponding circuit elements. For example, a plurality of active regions may be defined in the semiconductor layer 103, which may be understood as “semiconductor islands” in which an appropriate dopant profile may be established so as to obtain the desired electronic behavior of one or more circuit elements to be formed in and above a corresponding active region. For example, an active region 103A may be formed in the semiconductor layer 103, for instance on the basis of an appropriate isolation structure (not shown) which may laterally enclose the active region 103A and which may extend to a specified depth within the semi-conductor layer 103, for instance down to the buried insulating layer 102, if provided. In the embodiment shown, the active region 103A may represent an active region for forming therein and thereabove an N-channel transistor, wherein the active region 103A may have an appropriate crystallographic configuration to provide enhanced transistor performance upon creating a tensile strain component along a current flow direction, which is the horizontal direction in FIG. 1a. For example, the current flow direction in the active region 103A may correspond to a <110> direction, along which a tensile strain component may result in an increase of electron mobility, which may thus provide enhanced overall transistor performance. It should be appreciated that, in other illustrative embodiments, any other circuit elements may be formed in and above the active region 103A, in which a corresponding tensile strain component may be advantageous. For instance, a tensile strain component may also be advantageous for P-channel transistors if the current flow direction may be oriented along a crystallographic <100> direction.

Thus, depending on the overall process strategy, one or more circuit features may be formed above the active region 103A, such as electrode structures and the like, as required for the further processing of the semiconductor device 100. For example, a gate electrode structure 105 may be formed on the active region 103A in accordance with design rules for transistor elements of the semiconductor device 100. For example, the gate electrode structure 105 may comprise an electrode material 105A, for instance in the form of polysilicon and the like, which may be formed on a gate insulation layer 105B that separates the electrode material 105A from a channel region 106. For instance, in sophisticated semiconductor devices, a gate length, i.e., in FIG. 1a, the horizontal extension of the electrode material 105A, may be approximately 50 nm and less, depending on the overall design rules. Furthermore, at any appropriate manufacturing stage of the semiconductor device 100, a hydrogen species 110 may be incorporated into exposed portions of the semiconductor layer 103 in order to create a certain degree of lattice distortion, thereby also creating a desired type of strain, for instance in the channel region 106. The incorporation of the hydrogen species 110 may be accomplished by establishing an appropriate ambient 107, for instance by providing hydrogen gas at an elevated temperature, for instance at approximately 80-200° C. and higher, while maintaining a specific hydrogen concentration in the ambient 107. In other illustrative embodiments, as will be explained later on in more detail, the hydrogen species may be provided in the form of a hydrogen-containing material layer that may be in direct contact with the semiconductor layer 103 or which may be in contact via a thin intermediate material, if desired. Thus, within the ambient 107, hydrogen may be driven into exposed portions of the semiconductor layer 103 while substantially not destroying the crystalline state of the semiconductor layer 103. Consequently, a significant lattice distortion along the depth direction, as indicated by 103D, may be created by incorporating the hydrogen species into the lattice structure, thereby creating a tensile strain component 106S in and below the channel region 106, which may have a substantially reduced hydrogen concentration due to the lack of any exposed surface areas, which may enable a direct incorporation of the hydrogen species 110. Consequently, after the incorporation of the hydrogen species 110 by means of the ambient 107, a moderately high hydrogen concentration may be obtained adjacent to the channel region 106, which may amount to approximately one to several atomic percent compared to the material composition of the basic semiconductor layer 103.

FIG. 1b schematically illustrates the semiconductor device 100 according to illustrative embodiments in which the hydrogen species 110 (FIG. 1a) may be incorporated into portions of the active region 103A during the process sequence for forming a transistor element. In the manufacturing stage shown, the gate electrode structure 105A may have formed on the sidewalls thereof an appropriate spacer element 105C so as to define a desired offset for forming drain and source extension regions 108E, for instance by ion implantation, in accordance with well-established process recipes. In the embodiment shown, the gate electrode structure 105 and the drain and source extension regions 108E may represent a part of an N-channel transistor 150. Thus, the extension regions 108E may be formed on the basis of an N-type dopant species.

FIG. 1c schematically illustrates the semiconductor device 100 during an anneal process 109, which may be performed on the basis of any appropriate anneal recipe, for instance using flashlight-based anneal techniques, laser-based anneal techniques, rapid thermal anneal processes and the like, depending on the overall process strategy. During the anneal process 109, a certain degree of dopant diffusion, if desired, may be initiated, while implantation-induced lattice damage may also be re-crystallized, thereby obtaining a substantially crystalline state of the active region 103A and in particular of the drain and source extension regions 108E.

The transistor 150 as shown in FIGS. 1b and 1c may be formed on the basis of well-established manufacturing techniques. That is, after providing the semiconductor layer 103 and defining the active region 103A therein, for instance on the basis of isolation structures (not shown), which may involve sophisticated lithography, etch, deposition and planarization techniques, a gate dielectric material may be formed, followed by the deposition of the electrode material 105A. Thereafter, the corresponding material layers, possibly in combination with additional materials, such as anti-reflective coating (ARC) materials, cap materials and the like, may be patterned using sophisticated lithography and etch techniques. It should be appreciated that, if desired, at any manufacturing stage, a hydrogen species, such as the species 110 as shown in FIGS. 1a, may be incorporated into at least a portion of the semiconductor layer 103 by means of the ambient 107 (FIG. 1a) or by a hydrogen-containing material layer, as will be described later on in more detail. After the patterning of the electrode material 105A, the spacer element 105C may be formed, if required, and thereafter well-established implantation techniques may be used for forming the extension regions 108E, the crystalline state of which may be re-established by performing the anneal process 109, as discussed above. It should be appreciated that the anneal process 109 may be omitted in this manufacturing stage and may be performed in a later stage, after forming deep drain and source areas on the basis of a further implantation process if a strain-inducing sequence on the basis of incorporated hydrogen species may not be desired in this stage.

FIG. 1d schematically illustrates the semiconductor device 100 according to illustrative embodiments in which a hydrogen-containing material layer 117 may be formed above exposed surface portions of the semiconductor layer 103 and also above the gate electrode structure 105. For example, the hydrogen-containing material layer 117 may be a dielectric material, such as silicon nitride, silicon dioxide, silicon oxynitride and the like, in which, additionally, hydrogen may be incorporated. As previously explained, the layer 117 may represent, in some illustrative embodiments, a hydrogen-enriched material layer, which may be understood as a hydrogen-containing material layer having a content of hydrogen as defined above. For example, in some illustrative embodiments, the layer 117 may represent a silicon nitride layer having incorporated therein a hydrogen content of approximately 5-25 atomic percent. Moreover, a thickness of the layer 117 may range from several nanometers, such as 5-20 nm and more, depending on the overall device dimensions. The layer 117 may be formed on the basis of well-established process techniques, such as plasma enhanced CVD, thermally activated CVD and the like, wherein the fraction of hydrogen incorporated in the layer 117 may be adjusted by using appropriate process parameters, such as deposition pressure, temperature, the ratio of the flow rates of the corresponding precursor and carrier materials, the degree of ion bombardment created during a plasma assisted deposition technique and the like.

FIG. 1e schematically illustrates the semiconductor device 100 during an electron bombardment 107A, which may be understood as any process for incorporating electrons in the layer 117. For instance, electrons may be created and accelerated by appropriate devices, such as plasma-generating devices, electron accelerators and the like, as may, for instance, be used in electron microscopy and the like. For example, depending on the thickness of the layer 117, the electron bombardment 107A may be performed on the basis of an accelerating energy of one to several keV, wherein a current density of several pA per cm² or higher may be applied. Although the exact mechanism is not yet understood, it is assumed that, upon the electron bombardment 107A, hydrogen may be transferred from the layer 117 into the semiconductor layer 103, wherein the hydrogen species may be incorporated such that the basic lattice structure may not be substantially destroyed while at the same time, however, a significant distortion may occur.

FIG. 1f schematically illustrates the semiconductor device 100 during and after the electron bombardment 107A, which may result in a distortion along the depth direction 103D, thereby creating the desired tensile strain component 106S, as is also previously explained with reference to FIG. 1a. Thus, the strain 106S may be obtained without requiring an additional amorphizing step, as may be the case in conventional stress memorization techniques, while at the same time the strain component 106S may be obtained along the entire depth of the semiconductor layer 103 by distributing the hydrogen species 110 substantially along the entire depth 103D. It should be appreciated that the process sequence for forming the layer 117 and performing the electron bombardment 107A may be applied at any appropriate manufacturing stage, that is, prior to forming the gate electrode structure 105 and prior to forming the extension regions 108E, or a corresponding sequence may be applied repeatedly if an overall enhanced strain component may be required. Performing the sequence including the deposition of the layer 117 and the electron bombardment 107A after annealing the drain and source extension regions 108E may enable an efficient strain-inducing mechanism, wherein lattice damage, which may be caused by any other preceding implantation processes such as pre-amorphization implantation, halo implantation and the like, may also be re-crystallized, thereby providing appropriate conditions for establishing the strain component 106S by using the above-described mechanism. After the electron bombardment 107A, in some illustrative embodiments, the layer 117 may be removed, for instance on the basis of well-established selective etch recipes, such as using hot phosphoric acid, when the layer 117 is substantially comprised of silicon nitride. In other cases, any other appropriate etch recipes may be used, depending on the overall material composition of the layer 117. It should be appreciated that, if desired, the layer 117 may be provided in combination with a thin etch stop layer, such as a silicon dioxide layer, when undue exposure to an etch ambient for removing the layer 117 may be considered inappropriate.

Thereafter, the further processing may be continued by forming a spacer structure and deep drain and source regions in accordance with well-established process techniques, followed by forming metal silicide regions, if required.

In still other illustrative embodiments, the layer 117 may be used during the further processing, for instance for forming spacer elements. For this purpose, the hydrogen-containing material layer 117 may be provided with an appropriate thickness as may be required for obtaining a desired spacer width, wherein optionally, as previously discussed, an etch stop liner material may be provided in combination with the layer 117. For example, silicon dioxide in combination with silicon nitride as a spacer material may be formed in accordance with appropriate deposition techniques, wherein a desired high hydrogen content may be incorporated into the layer 117, as previously explained. Thus, after the electron bombardment 107A, the layer 117 may be etched in accordance with well-established anisotropic etch techniques, thereby providing the desired spacer elements. In other illustrative embodiments, the layer 117 may be used as an etch stop material for a spacer material to be formed on the layer 117. For example, the layer 117 may be provided in the form of a hydrogen-enriched silicon dioxide material on which may be deposited a spacer material, such as silicon nitride and the like. In still other illustrative embodiments, the layer 117 may be provided as a hydrogen-enriched silicon nitride material, while subsequently a spacer material may be deposited, for instance in the form of a silicon dioxide material.

FIG. 1g schematically illustrates the semiconductor device 100 in a further advanced manufacturing stage. As illustrated, a spacer structure 105D may be provided, possibly in combination with an etch stop layer 118, which, in some illustrative embodiments, may be represented by the layer 117 (FIG. 1f), while in other cases the layer 117 may have been removed, as previously explained. Similarly, the spacer structure 105D may represent a portion of the material layer 117 in some illustrative embodiments, while in other cases the spacer element 105D may be formed on the basis of a separately deposited spacer material, such as silicon nitride. Furthermore, in the manufacturing stage shown, deep drain and source regions 108D may be formed so as to have a lateral offset to the channel region 106 as defined by the spacer element 105D. It should be appreciated that two or more spacer elements may be provided, depending on the complexity of the lateral dopant profile for the drain and source regions, including the extension regions 108E and the deep drain and source regions 108D. The deep drain and source regions 108D may be formed in accordance with well-established implantation techniques, thereby also creating heavy lattice damage therein while, however, the hydrogen species 110 provided in a portion of the active region 103A, which may be protected by the spacer element 105D, may still induce the desired type of strain 106S. Similarly, the extension region 108E covered by the spacer element 105D may also exhibit the desired type of strain due to the hydrogen species 110, previously incorporated during the electron bombardment 107A (FIG. 1e). After forming the deep drain and source regions 108D by ion implantation, a further anneal process may be performed to activate the dopants and re-crystallize the implantation-induced damage in the region 108D. As previously explained, in some illustrative embodiments, the extension regions 108E may still be in a substantially amorphized state and may also be re-crystallized during a corresponding anneal process. In this case, the hydrogen species 110 may not be incorporated in the active region 103A. After re-crystallizing damaged portions of the drain and source regions 108D, the further processing may be continued by forming a hydrogen-containing material layer so as to apply the strain-inducing mechanism, as previously described.

FIG. 1h schematically illustrates a further material layer 119, such as a silicon nitride layer and the like, which may comprise a desired amount of hydrogen species, as previously explained with reference to the layer 117. Thereafter, an electron bombardment 107B may be performed, as previously described with reference to the process 107A (FIG. 1e) in order to drive the hydrogen species into the drain and source regions so as to obtain the desired distortion without damaging the lattice structure. Hence, also in this case, a desired type of strain component may be obtained. As explained above, in some illustrative embodiments, the strain component 106S obtained on the basis of the material layer 117 and the electron bombardment 107A (see FIG. 1e) may be combined with the additional strain component obtained by the mechanism provided by the layer 119 and the electron bombardment 107B, thereby enhancing the overall strain in the channel region 106. Thereafter, the material layer 119 may be removed, for instance on the basis of selective etch recipes wherein, depending on the material composition of the spacer element 105D (FIG. 1g), this spacer element may also be removed in a common etch process. In other cases, the material 119 may be selectively removed while maintaining the spacer element 105D. Next, metal silicide regions (not shown) may be formed in the drain and source regions and possibly in the gate electrode structure 105, as required by the overall process strategy.

As a result, the present disclosure provides techniques and semiconductor devices in which a lattice structure may be efficiently distorted by incorporating a hydrogen species, which may result in a desired type of strain for enhancing device characteristics of sophisticated semiconductor devices. In some illustrative embodiments, the effect of lattice distortion on the basis of a hydrogen species may be used in sophisticated field effect transistors in order to create a distortion perpendicular to the current flow direction, which may translate into a desired type of strain along the current flow direction. For this purpose, in some illustrative embodiments, a hydrogen-containing material layer, such as silicon nitride and the like, may be provided and may be treated on the basis of an electron shower, thereby driving the hydrogen species into the active semiconductor material, substantially without destroying the lattice structure. Consequently, the moderately high hydrogen concentration may result in a corresponding strain component in the adjacent channel region. For example, a maximum hydrogen concentration in strain-inducing portions of the active region may be approximately 5 atomic percent and even higher, thereby resulting in a significant tensile strain component, which may enhance transistor performance of N-channel transistors for standard crystal configuration of the active region, while also providing the possibility of enhancing performance of other circuit elements, such as P-channel transistors, if an appropriate crystallographic configuration with respect to the current flow direction may be selected. The process sequence for incorporating the hydrogen species may be applied at any appropriate manufacturing stage prior to forming metal silicide regions, while, in some illustrative embodiments, the corresponding sequence may be applied more than once so as to provide overall enhanced strain-inducing mechanism. Furthermore, the strain-inducing mechanism described above may be advantageously combined with other mechanisms, such as the provision of strain-inducing dielectric materials formed above the transistor structures, strain-inducing semiconductor alloys provided adjacent to the channel region and the like. Furthermore, the strain-inducing mechanism based on the incorporation of a hydrogen species may also be combined with conventional stress memorization techniques, which may require the re-crystallization of a substantially amorphized portion of the active region in the presence of a cap layer.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a gate electrode structure above an active region located in a silicon-containing crystalline semiconductor layer; and
driving a hydrogen species into an exposed surface portion of said crystalline semiconductor layer so as to deform a lattice structure of at least a portion of said active region.

2. The method of claim 1, further comprising forming drain and source regions in said active region laterally offset from said gate electrode structure.

3. The method of claim 1, wherein driving said hydrogen species into an exposed surface portion of said crystalline semiconductor layer comprises forming a hydrogen-containing material layer above said semiconductor layer and said gate electrode structure and exposing said hydrogen-containing material layer to an electron shower.

4. The method of claim 3, wherein said hydrogen-containing material layer additionally comprises silicon and nitrogen.

5. The method of claim 3, wherein said electron shower is established as an electron beam.

6. The method of claim 3, further comprising removing said hydrogen-containing material layer.

7. The method of claim 3, further comprising using said hydrogen-containing material layer for forming a spacer element at sidewalls of said gate electrode structure.

8. The method of claim 2, further comprising forming metal silicide regions in said drain and source regions after driving in said hydrogen species.

9. The method of claim 8, wherein said hydrogen species is driven in after forming said deep drain and source portions of said drain and source regions.

10. The method of claim 2, wherein said hydrogen species is driven in at least once prior to forming said drain and source regions.

11. The method of claim 2, wherein said drain and source regions are formed by using an N-type dopant species.

12. A method, comprising:
forming a hydrogen-containing material layer on a crystalline semiconductor layer; and
performing an electron bombardment on said hydrogen-containing material layer so as to create a strained crystalline state of at least a portion of said crystalline semiconductor layer.

13. The method of claim 12, further comprising forming a gate electrode structure of a transistor above said crystalline semiconductor layer prior to forming said hydrogen-containing material layer.

14. The method of claim 13, further comprising removing said hydrogen-containing material layer prior to completing said transistor.

15. The method of claim 13, further comprising forming shallow drain and source regions prior to performing said electron bombardment.

16. The method of claim 14, further comprising forming deep drain and source regions in said drain and source areas prior to performing said electron bombardment.

17. The method of claim 15, further comprising using said hydrogen-containing material layer for forming a sidewall spacer on sidewalls of said gate electrode structure of said transistor.

18. The method of claim 17, further comprising forming deep drain and source regions using said sidewall spacer as an implantation mask and re-crystallizing said deep drain and source regions.

19. The method of claim 18, further comprising forming a second hydrogen-containing material layer above said active region and driving in a hydrogen species from said second hydrogen-containing material layer.

20. The method of claim 19, further comprising removing said second hydrogen-containing material layer and forming metal silicide regions in said drain and source regions.

21. A field effect transistor, comprising:
an active region comprising silicon material in a crystalline state;
drain and source regions formed in said active region, said drain and source regions comprising a strain-inducing region having a distorted lattice structure, said strain-inducing region having a higher hydrogen concentration compared to remaining areas of said active region; and
a gate electrode structure formed on a channel region of said active region.

22. The field effect transistor of claim 21, wherein said drain and source regions are comprised of an N-type dopant species.

23. The field effect transistor of claim 22, wherein a maximum concentration of said hydrogen species in said strain-inducing regions is approximately 5 atomic percent or higher.
